(19) United States
(12) Patent Application Publication
(10) Pub. No.: US 2025/0221203 A1
(43) Pub. Date: Jul. 3, 2025

(54) DISPLAY APPARATUS

(71) Applicant: LG Display Co., Ltd., Seoul (KR)

(72) Inventors: KwangYong CHOI, Paju-si (KR); ByeongUk GANG, Paju-si (KR)

(73) Assignee: LG Display Co., Ltd., Seoul (KR)

(21) Appl. No.: 18/899,898

(22) Filed: Sep. 27, 2024

(30) Foreign Application Priority Data
Dec. 29, 2023 (KR) 10-2023-0197326

(51) Int. Cl. H10K 59/131; H10K 59/126

(52) U.S. Cl. CPC H10K 59/131; H10K 59/126

(57) ABSTRACT

A display apparatus according to an embodiment of the present disclosure includes a substrate having a display area in which a plurality of sub-pixels are disposed and a non-display area surrounding the display area; and a pixel power line extending from the non-display area to the display area, wherein each of the plurality of sub-pixels comprises a light emission area and a circuit area adjacent to the light emission area, and wherein the pixel power line comprises: a first pixel power line disposed along one edge of one of the plurality of sub-pixels; and a second pixel power line partially overlapping the circuit area and extending from the first pixel power line.

### CROSS-REFERENCE TO RELATED APPLICATIONS

This application claims the benefit of the Korean Patent Applications No. 10-2023-0197326 filed on Dec. 29, 2023, which is hereby incorporated by reference as if fully set forth herein.

### BACKGROUND

### Technical Field

The present disclosure relates to a display apparatus displaying images.

### Discussion of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

On the other hand, a display apparatus includes a light emission area in which a light emitting element layer emits light, and a circuit area for emitting the light emission area, and when the area of the circuit area is large, the area of the light emission area becomes relatively small, decreasing light efficiency. Therefore, research is being conducted to reduce the area of the circuit area, but when the area of the circuit area becomes small, the area of the wiring disposed in the circuit area also becomes small, increasing power consumption, which limits the improvement.

### SUMMARY

Accordingly, embodiments of the present disclosure are directed to a display apparatus that substantially obviates one or more of the problems due to limitations and disadvantages of the related art.

An aspect of the present disclosure is to provide a display apparatus capable of improving light efficiency.

Another aspect of the present disclosure is to provide a display apparatus that may have reduced power consumption.

Another aspect of the present disclosure is to provide a display apparatus capable of reliably driving a light emitting element layer.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a substrate having a display area in which a plurality of sub-pixels are disposed and a non-display area surrounding the display area; and a pixel power line extending from the non-display area to the display area, wherein each of the plurality of sub-pixels comprises a light emission area and a circuit area adjacent to the light emission area, and wherein the pixel power line comprises: a first pixel power line disposed along one edge of one of the plurality of sub-pixels; and a second pixel power line partially overlapping the circuit area and extending from the first pixel power line.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the disclosure.

FIG. 1 is a schematic plan view of a display apparatus according to one embodiment of the present disclosure.

FIG. 2 is a schematic plan view of a single pixel illustrated in FIG. 1.

FIG. 3 is a schematic cross-sectional view of the line I-I′ shown in FIG. 1.

FIG. 4A is a schematic enlarged view of portion A shown in FIG. 2.

FIG. 4B is a schematic cross-sectional view of the line II-II′ shown in FIG. 4A.

FIG. 5A is a schematic enlarged view of portion B shown in FIG. 2.

FIG. 5B is a schematic cross-sectional view of the line III-III′ shown in FIG. 5A.

FIG. 6A is a schematic enlarged view of another example of FIG. 5A.

FIG. 6B is a schematic cross-sectional view of lines IV-IV′ shown in FIG. 6A.

FIG. 7A is a schematic enlarged view illustrating another example of FIG. 5A.

FIG. 7B is a schematic cross-sectional view of the line V-V′ shown in FIG. 7A.

FIG. 8 is a schematic plan view of a display apparatus according to a second embodiment of the present disclosure.

FIG. 9A is a schematic enlarged view of portion C shown in FIG. 8.

FIG. 9B is a schematic cross-sectional view of the line VI-VI′ shown in FIG. 9A.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used. It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

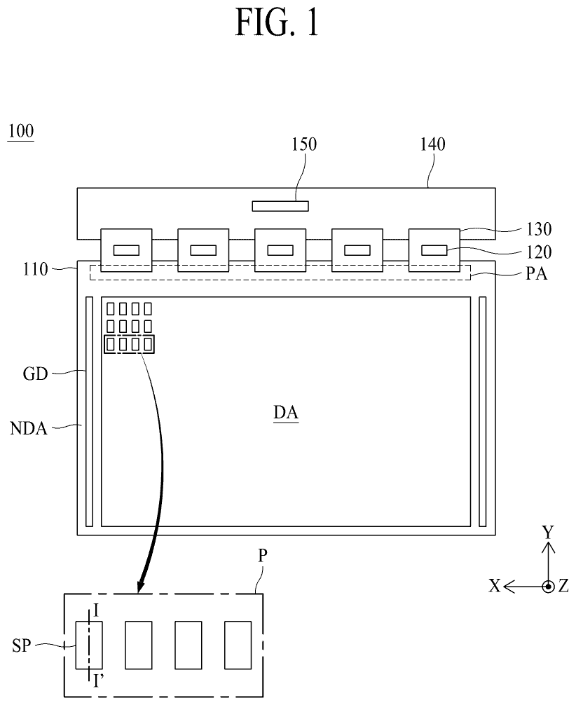

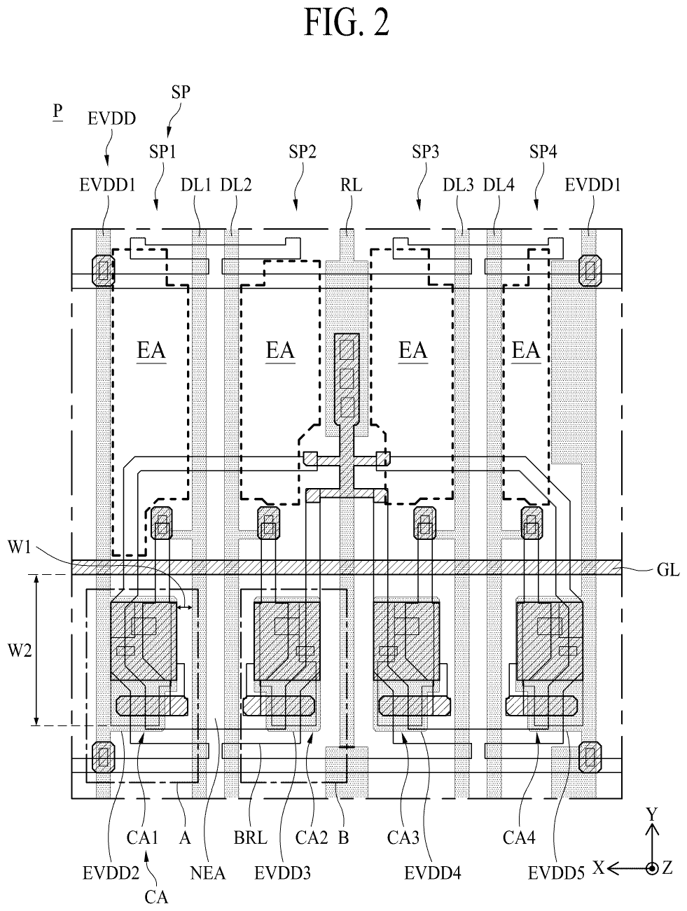

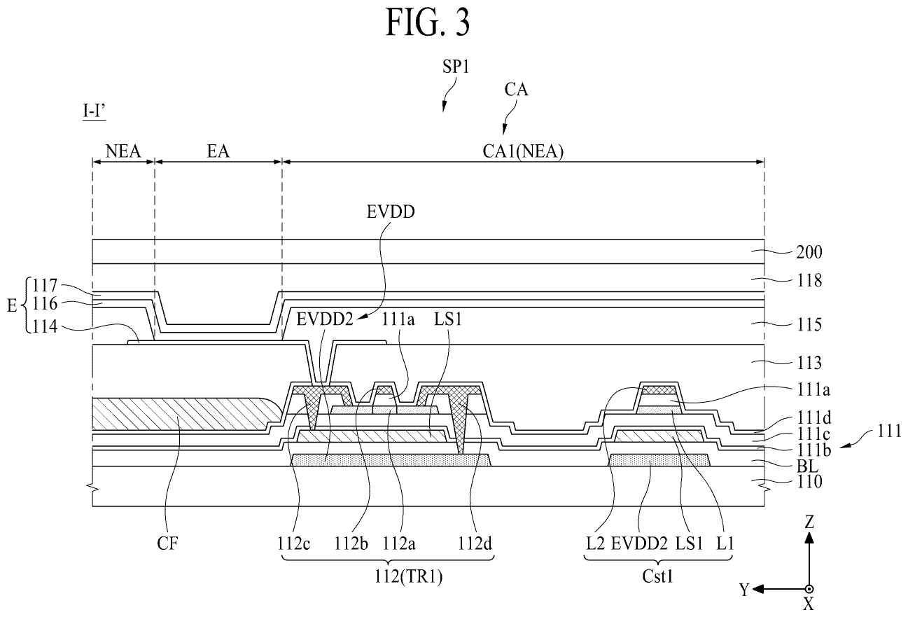

FIG. 1 is a schematic plan view of a display apparatus according to one embodiment of the present disclosure, FIG. 2 is a schematic plan view of a single pixel illustrated in FIG. 1, and FIG. 3 is a schematic cross-sectional view of the line I-I′ shown in FIG. 1.

Referring now to FIGS. 1 to 3, a display apparatus 100 according to one embodiment of the present disclosure includes a substrate 110, and a pixel power line EVDD. The substrate 110 includes a display area DA on which a plurality of sub-pixels SPs are disposed, and a non-display area NDA surrounding the display area DA. The pixel power line EVDD is disposed extending from the non-display area NDA to the display area DA. The plurality of sub-pixels SPs may include a light emission area EA and a circuit area CA adjacent to the light emission area EA.

Here, the pixel power lines EVDDs may include a first pixel power line EVDD1 disposed along one edge of a sub-pixel of one of the plurality of sub-pixels SP, and a second pixel power line EVDD2 partially overlapping the circuit area CA and disposed extending from the first pixel power line EVDD1.

In the case of a conventional display apparatus, the pixel power line is spaced apart at a predetermined distance from the circuit area to prevent the voltage supplied through the pixel power line from affecting the circuit area for driving the sub-pixels. Therefore, in the case of a conventional display apparatus, the circuit area has an area greater than or equal to a certain area, resulting in a relatively small area of the light emission area, which decreases the light efficiency or limits the improvement of the light efficiency.

In contrast, the display apparatus 100 according to one embodiment of the present disclosure may be configured such that the pixel power line EVDD (or the second pixel power line EVDD2) partially overlaps the circuit area CA, thereby reducing the area of the circuit area CA. Accordingly, the display apparatus 100 according to one embodiment of the present disclosure may increase the area of the light emission area EA relatively, and thus, the light efficiency may be improved compared to a conventional display apparatus.

For example, referring to FIG. 2, the display apparatus 100 according to one embodiment of the present disclosure is disposed such that the second pixel power line EVDD2 is not spaced apart from the first pixel power line EVDD1, the second pixel power line EVDD2 is disposed extending from the first pixel power line EVDD1 in a first direction (X-axis direction) (or in a direction to the right of the first direction (X-axis direction)), so that a horizontal width W1 formed between the second pixel power line EVDD2 and a first data line DL1 may be omitted (or eliminated). Here, extending may mean that the first pixel power line EVDD1 and the second pixel power line EVDD2 are not spaced apart but formed integrally, without separate connecting wiring (or branch wiring).

Further, as shown in FIG. 3, the display apparatus 100 according to one embodiment of the present disclosure may be configured such that the second pixel power line EVDD2 partially overlaps a thin film transistor (or first thin film transistor TR1) included in a circuit area CA.

Therefore, the display apparatus 100 according to one embodiment of the present disclosure is provided with the second pixel power line EVDD2 and the first pixel power line EVDD1 extending integrally without being spaced apart, as shown in FIG. 2, so that the area of the circuit area CA may be reduced by the omitted (or eliminated) horizontal width W1 (or horizontal length W1), and thus the area of the light emission area EA may be increased relatively, thereby improving the light efficiency. Since the second pixel power line EVDD2 is an area extended from the first pixel power line EVDD1, it may be expressed in terms of the first pixel line extension area or the first pixel line extension portion.

FIG. 2 illustrates a horizontal width W1 parallel to the first direction (X-axis direction), which is a horizontal direction of the display apparatus. Here, the circuit area CA may be configured such that the horizontal area of the circuit area CA may be increased in the first direction (X-axis direction) by the horizontal width W1 omitted between the second pixel power line EVDD2 and the first pixel power line EVDD1, and the perpendicular area of the circuit area CA may be decreased in the second direction (Y-axis direction), which is a perpendicular direction, accordingly, the circuit area CA may be configured such that the circuit area CA has a decreased perpendicular width W2 (or vertical length W2).

In FIG. 2, it has been described to increase the area of the light emission area EA disposed on the upper side (or in the second direction (Y-axis direction)) of the circuit area CA by widening the horizontal area of the circuit area CA by the reduced horizontal width W1 while simultaneously reducing the perpendicular area of the circuit area CA, but it is not limited thereto, and the shape of the circuit area CA may be varied depending on the arrangement structure of the light emission area EA and the circuit area CA (or the request of the user).

As such, the display apparatus 100 according to one embodiment of the present disclosure is configured such that the pixel power line EVDD (or the second pixel power line EVDD2 extended from the first pixel power line EVDD1) partially overlaps the circuit area CA, thus the area of the light emission area EA may be increased in accordance with the decrease in the area of the circuit area CA, thereby improving the light efficiency.

Furthermore, the display apparatus 100 according to one embodiment of the present disclosure has the first pixel power line EVDD1 and the second pixel power line EVDD2 formed integrally without being spaced apart, thus the overall area of the pixel power line may be increased (or the resistance of the first pixel power line EVDD1, which is the main wiring, may be reduced), and the current density may be reduced, thereby enabling it to be driven with low power, thereby reducing the overall power consumption.

Hereinafter, reference to FIGS. 1 to 3, the display apparatus 100 according to an embodiment of the present specification will be described in more detail.

Referring to FIGS. 1 and 3, the display apparatus 100 according to one embodiment of the present disclosure may further include a display panel including a gate driver (GD), the source drive integrated circuit (hereinafter referred to as “IC”) 120, the flexible film 130, the circuit board 140, and the timing controller 150.

The display panel may include a substrate 110 and an opposite substrate 200 (shown in FIG. 3) bonded together.

The substrate 110 may include a thin film transistor, and may be a transistor array substrate, a lower substrate, a base substrate, or a first substrate. The substrate 110 may be a transparent glass substrate or a transparent plastic substrate. Hereinafter, the substrate 110 will be defined as a first substrate.

The opposing substrate 200 may be facing and bonded to the first substrate 110 via an adhesive member. For example, the opposing substrate 200 may have a smaller size than the first substrate 110 and may be facing and bonded to a portion of the first substrate 110 except the pad portion PA. The opposing substrate 200 may be an upper substrate, a second substrate, or an envelope substrate. Hereinafter, the opposing substrate 200 is defined as the second substrate.

The gate driver GD supplies gate signals to the gate lines in accordance with the gate control signal input from the timing controller 150. When the source drive IC 120 is manufactured as a driving chip, the source drive IC 120 may be packaged in the flexible film 130 in a chip on film (COF) method or a chip on plastic (COP) method.

Pads, such as power pads, data pads, may be formed in the non-display area of the display panel. Lines connecting the pads with the source drive IC 120 and lines connecting the pads with lines of the circuit board 140 may be formed in the flexible film 130. The flexible film 130 may be attached onto the pads by using an anisotropic conducting film, whereby the pads may be connected with the lines of the flexible film 130.

Referring to FIGS. 1 and 3, the first substrate 110 according to an example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

A display area DA according to one example may include gate lines, data lines, pixel power lines EVDDs, and a plurality of pixels P. Each of the plurality of pixels P may include a plurality of sub-pixels SPs that may be defined by the gate lines and the data lines. Each of the plurality of sub-pixels SPs may include the light emission area EA and the circuit area CA adjacent to the light emission area EA.

The light emission area EA according to one example may be defined as an area of the smallest unit in which actual light is emitted. The circuit area CA according to one example may be defined as an area in which a thin film transistor (or a thin film transistor and a storage capacitor) for emitting the light emission area EA is provided. For example, the thin film transistors may include a first thin film transistor TR1 (shown in FIG. 3), disposed in a first circuit area CA1 of a first sub-pixel SP1, a second thin film transistor disposed in a second circuit area CA2 of a second sub-pixel SP2, a third thin film transistor disposed in a third circuit area CA3 of a third sub-pixel SP3, and a fourth thin film transistor disposed in a fourth circuit area CA4 of a fourth sub-pixel SP4.

As shown in FIG. 2, the circuit area CA may be disposed adjacent to one side of the light emission area EA. For example, the light emission area EA and the circuit area CA may be disposed in the second direction (Y-axis direction), thereby being disposed parallel to the pixel power line EVDD (or the first pixel power line EVDD1). The pixel power line EVDD may be disposed extending from the non-display area NDA to the display area DA. For example, the pixel power line EVDD may be connected to a pad portion PA disposed in the non-display area NDA, and may receive power from the pad portion PA to apply a voltage to a plurality of sub-pixels SPs disposed in the display area DA, so that the plurality of sub-pixels SPs may be emitted.

On the other hand, at least four sub-pixels SPs configured to emit different colors and to dispose adjacent to each other among the plurality of sub-pixels SPs may constitute a single pixel P (or unit pixel). The one pixel P may include, but is not limited to, a red sub-pixel, a green sub-pixel, a blue sub-pixel, and a white sub-pixel. For example, the red sub-pixel may be the first sub-pixel SP1, the green sub-pixel may be the second sub-pixel SP2, the blue sub-pixel may be the third sub-pixel SP3, and the white sub-pixel may be the fourth sub-pixel SP4.

According to another example, one pixel P may comprise three sub-pixels SPs disposed adjacent to each other and configured to emit different colors. The one pixel P may comprise the red sub-pixel, the green sub-pixel, and the blue sub-pixel.

Each of the plurality of sub-pixels SPs may include a thin film transistor, and a light emitting element layer (E, shown in FIG. 3) connected to the thin film transistor. Each of the plurality of sub-pixels SPs may include a light emitting layer 116 (or organic light emitting layer 116) interposed between a pixel electrode 114 (or anode electrode 114) and a common electrode 117 (or reflective electrode 117).

The light emitting element layers respectively disposed in the plurality of subpixels SP may individually emit light of their respective colors different from one another or commonly emit white light. According to an example, when the light emitting layers of the plurality of subpixels SP commonly emit white light, each of the red subpixel, the green subpixel and the blue subpixel may include a color filter CF (or wavelength conversion member CF) for converting white light into light of its respective different color. In this case, the white subpixel according to an example may not include a color filter. In the display apparatus 100 according to one embodiment of the present disclosure, the area with the red color filter may be the red sub-pixel SP1, the area with the green color filter may be the green sub-pixel SP2, the area with the blue color filter may be the blue sub-pixel SP3, and the area without the color filter may be the white sub-pixel SP4.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

On the other hand, each of the plurality of sub-pixels SPs emitting different colors may comprise four sub-pixels spaced apart from each other in the first direction (X-axis direction) as shown in FIG. 2, for example, the plurality of sub-pixels SPs may comprise the first sub-pixel SP1, the second sub-pixel SP2, the third sub-pixel SP3, and the fourth sub-pixel SP4. The first to fourth sub-pixels SP1, SP2, SP3, and SP4 may be of the same size, but are not limited thereto, and at least one of the first to fourth sub-pixels SP1, SP2, SP3, and SP4 may have a different shape and/or size. A description of the structure of each of the sub-pixels SPs will be described hereinafter with reference to FIG. 3.

The display area DA may include a plurality of sub-pixels SPs, and each of the plurality of sub-pixels SPs may include a light emission area EA and a circuit area CA, as shown in FIG. 2.

Further, the display area DA comprises the pixel power line EVDD (or the first pixel power line EVDD1), the first data line DL1, a second data line DL2, a reference line RL, a third data line DL3, and a fourth data line DL4. The pixel power line EVDD (or the first pixel power line EVDD1) is disposed in the second direction (Y-axis direction) along one edge (or left edge) of the first sub-pixel SP1. The first data line DL1 is disposed in the second direction (Y-axis direction) along the other edge (or right edge) of the first sub-pixel SP1. The second data line DL2 is disposed in the second direction (Y-axis direction) along one edge (or left edge) of the second sub-pixel SP2. The reference line RL is disposed in the second direction (Y-axis direction) along the other edge (or right edge) of the second sub-pixel SP2 and/or along one edge (or left edge) of the third sub-pixel SP3. The third data line DL3 is disposed in the second direction (Y-axis direction) along the other edge (or right edge) of the third sub-pixel SP3. The fourth data line DL4 is disposed in the second direction (Y-axis direction) along one edge (or left edge) of the fourth sub-pixel SP4. Further, it may include another first pixel power line EVDD1 disposed in the second direction (Y-axis direction) along the other edge (or right edge) of the fourth sub-pixel SP4. Also, the display area DA may further include a gate line GL disposed in the first direction (X-axis direction) across between the light emission area EA and the circuit area CA.

As shown in FIG. 2, the gate line GL and the first to fourth data lines DL1, DL2, DL3, DL4 may be disposed in an intersecting structure.

The pixel power line EVDD according to one example is for receiving power and/or image signals from at least one of the gate driver (GD) and the pad portion (PA) and transmitting the power and/or image signals to the plurality of sub-pixels SPs of the display area DA. Accordingly, the pixel power line EVDD may be provided in a plurality.

Meanwhile, as described above, the pixel power line EVDD comprises the first pixel power line EVDD1 disposed in the second direction (Y-axis direction) along the one edge of the first sub-pixel SP1, and the second pixel power line EVDD2 partially overlapping the first circuit area CA1 of the first sub-pixel SP1 and disposed extending in the first direction (X-axis direction) from the first pixel power line EVDD1 (or in a direction to the right of the first direction (X-axis direction)).

The gate line GL according to one example may be connected to the gate driver GD and each of the plurality of sub-pixels SP. Thus, the gate line GL may comprise a plurality of gate lines. In one example, the gate line GL may be connected to a thin film transistor 112 of the sub-pixel SP. Thus, each of the plurality of sub-pixel SPs may receive power and/or image signals through the pixel power line EVDD, the data line, and the gate line GL to output an integral image.

The non-display area NDA may be an area where an image is not displayed, and may be a peripheral circuit area, a signal supply area, a non-active area, or a bezel area. The non-display area NDA may be configured to be around the display area DA. That is, the non-display area NDA may be disposed to surround the display area DA.

The display apparatus 100 according to one embodiment of the present disclosure may have the pad portion PA disposed in the non-display area NDA. The pad portion PA may supply power and/or signals for the pixels P provided in the display area DA to output images.

The gate driver GD supplies gate signals to the gate lines according to the gate control signals input from the timing controller 150. The gate driver GD may be formed in a gate driver in panel (GIP) manner on one side of the display area DA of the display panel, or on the non-display area NDA both outsides of the display area DA, as shown in FIG. 1.

The plurality of sub-pixels SPs are configured to overlap with at least one of the pixel power line EVDD, the data line, and the gate line GL to emit predetermined light to display an image. The light emission area EA may an area corresponding to an area where the sub-pixels SPs emit light.

For example, the first sub-pixel SP1 may be configured to include the light emission area EA emitting red light, the second sub-pixel SP2 may be configured to include the light emission area EA emitting green light, the third sub-pixel SP3 may be configured to include the light emission area EA emitting blue light, and the fourth sub-pixel SP4 may be configured to include the light emission area EA emitting white light, but is not necessarily limited thereto. Each of the pixels P may further comprise sub-pixels that emit light of colors other than red, green, blue, and white. Further, the order of arrangement of each of the sub-pixels SP1, SP2, SP3, SP4 may be variously changed.

The display apparatus 100 according to one embodiment of the present disclosure may further include a buffer layer BL, a circuit element layer 111, the thin film transistor 112, a planarization layer 113 (or an overcoat layer 113), the pixel electrodes 114, a bank 115, an organic light emitting layer 116, a common electrode 117, and the color filter CF.

More specifically, each of the sub-pixels SPs according to one embodiment includes a circuit element layer 111, the planarization layer 113, the pixel electrode 114, the bank 115, the organic light emitting layer 116, the reflective electrode 117, and an encapsulation layer 118. The circuit element layer 111 is provided on a top surface of the buffer layer BL and including a gate insulating layer 111a, a first interlayer insulating layer 111b, a second interlayer insulating layer 111c, a passivation layer 111d. The planarization layer 113 is provided on the circuit element layer 111, the pixel electrode 114 is provided on the planarization layer 113, the bank 115 covers an edge of the pixel electrode 114. The organic light emitting layer 116 is disposed on the pixel electrode 114 and the bank 115. The reflective electrode 117 is disposed on the organic light emitting layer 116, and the encapsulation layer 118 is disposed on the reflective electrode 117.

In the circuit element layer 111, the thin film transistors 112 for driving the sub-pixel SP may be disposed. The circuit element layer 111 may also be expressed in terms of an inorganic film layer. The buffer layer BL may be included in the circuit element layer 111 along with the gate insulating layer 111a, the first interlayer insulating layer 111b, the second interlayer insulating layer 111c, and the passivation layer 111d. The pixel electrode 114, the organic light emitting layer 116, and the reflective electrode 117 may be included in the light emitting element layer E (shown in FIG. 3).

Referring to FIG. 3, the buffer layer BL may be formed between the first substrate 110 and the gate insulating layer 111a (or the first interlayer insulating layer 111b) to protect the thin film transistor 112. The buffer layer BL may be disposed entirely on one surface (or front surface) of the first substrate 110. The buffer layer BL may serve to prevent a material contained in the first substrate 110 from being diffused into a transistor layer during a high temperature process of the manufacturing process of the thin film transistor. Optionally, the buffer layer BL may be omitted as the case may be.

As shown in FIG. 3, the buffer layer BL may be configured to cover the pixel power line EVDD (or the second pixel power line EVDD2).

The thin film transistor 112 (or driving transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the sub-pixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the first substrate 110 or the buffer layer BL, which includes the active layer 112a.

The gate electrode 112b may be formed on the gate insulating layer 111a to overlap the channel area of the active layer 112a.

The first interlayer insulating layer 111b may be configured to cover a first light blocking layer LS1 disposed on the buffer layer BL. The first light blocking layer LS1 according to an example may be provided below the active layer 112a. The first light blocking layer LS1 may be provided between the first substrate 110 and the active layer 112a to block light incident through the first substrate 110 toward the active layer 112a, thereby minimizing threshold voltage changes of the transistors caused by external light.

On the other hand, in the display apparatus 100 according to one embodiment of the present disclosure, the first light blocking layer LS1 may be a conducting semiconductor or a transparent metal, as the second pixel power line EVDD2 may take over the light blocking role, and there may be no limitation on the type of transparent metal and semiconductor.

For example, semiconductors changed into conducting semiconductors or metals by a conducting process may be used. The transparent metal may be formed from a transparent conductive material (TCO) such as ITO, IZO, or a semi-transmissive conductive material such as magnesium (Mg), silver (Ag), or an alloy of magnesium (Mg) and silver (Ag).

The second interlayer insulating layer 111c may be disposed on the first interlayer insulating layer 111b. The second interlayer insulating layer 111c may be disposed between the active layer 112a and the first light blocking layer LS1 together with the first interlayer insulating layer 111b. Further, the second interlayer insulating layer 111c may be disposed between the first layer L1 and the first light blocking layer LS1 together with the first interlayer insulating layer 111b in the first storage capacitor Cst1. Thus, the second interlayer insulating layer 111c and the first interlayer insulating layer 111b may maintain a gap spacing between the first layer L1 and the first light blocking layer LS1. As a result, when different voltages are applied to each of the first layer L1 and the first light blocking layer LS1, the first layer L1 and the first light blocking layer LS1 may be utilized as the first storage capacitor Cst1 in which a capacitance may be stored.

The source electrode 112c may be formed on the gate insulating layer 111a overlapping the source area of the active layer 112a and electrically connected to the source area of the active layer 112a. Further, the source electrode 112c may be electrically connected to the first light blocking layer LS1 through source contact holes provided in the gate insulating layer 111a, the first and second interlayer insulating layer 111b, 111c.

The drain electrode 112d may be formed on the gate insulating layer 111a overlapping the drain area of the active layer 112a and electrically connected to the drain area of the active layer 112a. Further, the drain electrode 112d may be electrically connected to the pixel power line EVDD (or the second pixel power line EVDD2) through drain contact holes provided in the gate insulating layer 111a, the first and second interlayer insulating layer 111b, 111c, and the buffer layer BL.

The drain electrode 112d and the source electrode 112c may be made of the same met al material. For example, each of the drain electrode 112d and the source electrode 112c may be made of a single metal layer, a single layer of an alloy or a multi-layer of two or more layers, which is the same as or different from that of the gate electrode.

Additionally, the circuit area CA may further comprise the storage capacitor Cst disposed adjacent to the thin film transistor 112. The storage capacitors Cst may include a first storage capacitor Cst1 disposed in the first circuit area CA1 of the first sub-pixel SP1, a second storage capacitor Cst2 disposed in the second circuit area CA2 of the second sub-pixel SP2, a third storage capacitor disposed in a third circuit area CA3 of a third sub-pixel SP3, and a fourth storage capacitor disposed in a fourth circuit area CA4 of a fourth sub-pixel SP4.

For example, the first storage capacitor Cst1 may include the second pixel power line EVDD2, the first light blocking layer LS1 on the second pixel power line EVDD2, the first layer L1 disposed on the first light blocking layer LS1 and disposed on the same layer as the active layer 112a, and a second layer L2 disposed on the first layer L1 and disposed on the same layer as the gate electrode 112b.

As shown in FIG. 3, in the first storage capacitor Cst1, the buffer layer BL may be disposed between the second pixel power line EVDD2 and the first light blocking layer LS1. Also, the first interlayer insulating layer 111b and the second interlayer insulating layer 111c may be disposed between the first layer L1 and the first light blocking layer LS1. Further, in the first storage capacitor Cst1, the gate insulating layer 111a may be disposed between the first layer L1 and the second layer L2. The fourth storage capacitor may be provided with a stacked structure similar to the first storage capacitor Cst1. Also, the second storage capacitor may be provided with a stacked structure similar to the third storage capacitor.

Referring again to FIG. 3, the passivation layer 111d may be provided on the first substrate 110 to cover the pixel area. The passivation layer 111d may be provided to cover the drain electrode 112d, the source electrode 112c, and the gate electrode 112b of the thin film transistor 112, and the second layer L2. The passivation layer 111d may be formed on the entire circuit area CA and light emission area EA. Such passivation layer 111d may be omitted.

The planarization layer 113 may be provided on the first substrate 110 to cover the passivation layer 111d and the color filter CF. When the passivation layer 111d is omitted, the planarization layer 113 may be provided on the first substrate 110 to cover the circuit area CA. The planarization layer 113 may be formed on the entire circuit area CA and light emission area EA. Further, the planarization layer 113 may be formed the entire non-display area NDA and display area DA except for the pad portion PA of the non-display area NDA. For example, the planarization layer 113 may include an extension portion (or expansions) extending or expanding from the display area DA toward the remaining non-display area NDA except for the pad portion PA. Thus, the planarization layer 113 may have a relatively larger size than the display area DA.

The planarization layer 113 according to an example may be formed to be relatively thick, and thus may provide a flat surface on the display area DA and the non-display area NDA. For example, the planarization layer 113 may be made of an organic material such as photo acryl, benzocyclobutene, polyimide, and fluorine resin.

The color filter CF according to one example may be provided between the first substrate 110 (or passivation layer 111d) and the planarization layer 113. The color filter CF may include the red color filter (or first color filter) to convert white light emitted by the organic light emitting layer 116 into red light, the green color filter (or second color filter) to convert white light into green light, and the blue color filter to convert white light into blue light. The fourth sub-pixel, which is a white sub-pixel, may not include the color filter because the organic light emitting layer 116 emits white light.

The display apparatus 100 according to one embodiment of the present disclosure may have the color filters CF having different colors partially overlapping at the boundary portions of the plurality of sub-pixels SPs. Although not shown, a respective end portion of the color filter CF of the first sub-pixel SP1 and the color filter of the second sub-pixel SP2 may overlap each other at the boundary portion of the sub-pixels. Since the color filter CF of the first sub-pixel SP1 and the color filter CF of the second sub-pixel SP2 are formed sequentially rather than simultaneously, the end portions of each of the color filter CF of the first sub-pixel SP1 and the color filter of the second sub-pixel SP2 may overlap at the boundary portions of the sub-pixels SPs. Thus, the display apparatus 100 according to one embodiment of the present disclosure may prevent light emitted from each sub-pixel of the SPs from being emitted to an adjacent sub-pixel of the SPs due to the overlapping color filters at the boundary portions of the sub-pixels of the SPs, thereby preventing mixing between the sub-pixels of the SPs.

Referring to FIG. 3, the pixel electrodes 114 of the sub-pixel SP may be formed on the planarization layer 113. The pixel electrode 114 may be connected to a drain electrode or a source electrode of the thin film transistor 112 through a contact hole penetrating the planarization layer 113 and the passivation layer 111d. An edge portion of the pixel electrode 114 may be covered by the bank 115. The pixel electrodes 114 may be made of at least one of a transparent metallic material, and a semi-transparent metallic material.

Since the display apparatus 100 according to one embodiment of the present disclosure is provided in a bottom emission mode, the pixel electrode 114 may be formed of a transparent conductive material (TCO) such as ITO and IZO, which may transmit light, or a semi-transmissive conductive material such as magnesium (Mg), silver (Ag) or an alloy of magnesium (Mg) and silver (Ag).

Meanwhile, the material constituting the pixel electrode 114 may include MoTi. The pixel electrode 114 may be a first electrode or an anode electrode.

The bank 115 is an area where no light is emitted and may be configured to surround each of the light emitting portion of the plurality of sub-pixels SPs. That is, the bank 115 may partition (or define) the light emission area EA of each of the light emitting portion or sub-pixels SPs.

The bank 115 may be formed to cover an edge of each of the pixel electrodes 114 included in each of the sub-pixels SPs and leave a portion of each of the pixel electrodes 114 exposed. That is, the bank 115 may partially cover the pixel electrodes 114. Accordingly, the bank 115 may prevent the pixel electrodes 114 from contacting the reflective electrodes 117 at the ends of each of the pixel electrodes 114.

After the bank 115 is formed, the organic light emitting layer 116 may be formed to cover the pixel electrodes 114 and the bank 115. Thus, the bank 115 may be provided between the pixel electrode 114 and the organic light emitting layer 116 at an edge of the pixel electrode 114. Such banks 115 may be expressed in terms of pixel-defining membranes. The bank 115 according to one example may comprise an organic material. When the banks 115 are made of organic material, the banks 115 in the non-light emission area NEA may be provided with different thicknesses depending on their location. Furthermore, when the banks 115 are made of organic material, the top surface of the banks 115 may be flat, so that the organic light emitting layer 116, reflective electrode 117, and encapsulating layer 118 formed on the top surface of the banks 115 may also formed to be flat in a subsequent process. However, it is not limited thereto, the bank 115 may be made of an inorganic material.

Referring again to FIG. 3, the organic light emitting layer 116 may be formed on the pixel electrodes 114 and the bank 115. The organic light emitting layer 116 is provided between the pixel electrode 114 and the reflective electrode 117, so that when a voltage is applied to each of the pixel electrode 114 and the reflective electrode 117, an electric field is formed between the pixel electrode 114 and the reflective electrode 117, which may be emitted. The organic light emitting layer 116 may be formed of a plurality of sub-pixels SPs, and a common layer provided on the bank 115.

The organic light emitting layer 116 according to an embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The organic light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP.

According to another embodiment, the organic light emitting layer 116 may be provided to emit lights of different colors and may be patterned in each of the plurality of subpixels SP. However, in this case, a hole injection layer (HIL), a hole transport layer (HTL), an emission transport layer (ETL), and an electron injection layer (EIL) except the light emitting layer may be arranged as a common layer in the subpixels SP. Also, in a case where the light emitting layer 116 is patterned in each of the subpixels SP, a color filter may not be provided between the substrate 110 and the light emitting layer 116.

The reflective electrode 117 may be formed on the organic light emitting layer 116. The reflective electrode 117 according to one example may include a metal material. The reflective electrode 117 may reflect the light emitted from the organic light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the organic light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 may include at least one inorganic film and at least one organic film.

Meanwhile, as shown in FIG. 3, the encapsulation layer 118 may be disposed not only in the light emission area EA but also in the non-light emission area NEA. The encapsulation layer 118 may be disposed between the reflective electrode 117 and an opposing substrate 200.

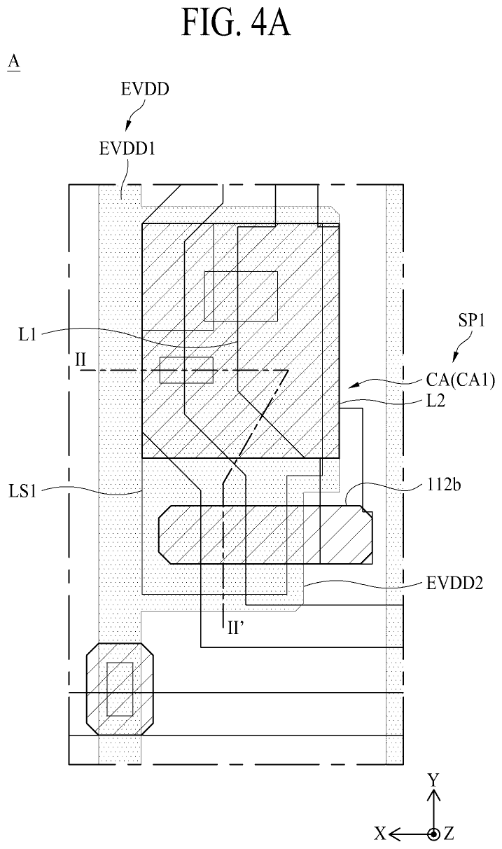

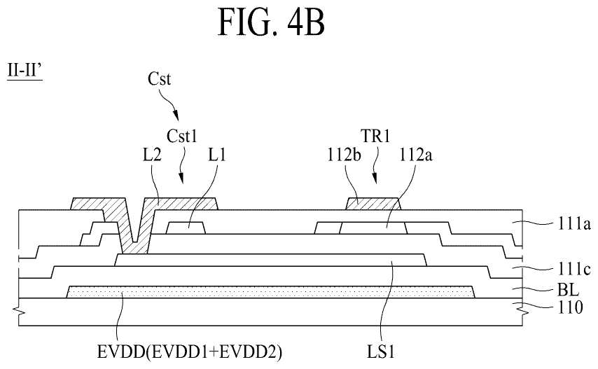

Hereinafter, with reference to FIGS. 4A and 4B, the circuit area CA (or non-light emission area NEA) of the display apparatus 100 according to one embodiment of the present disclosure will be described in more detail. FIG. 4A is a schematic enlarged view of the portion A shown in FIG. 2, and FIG. 4B is a schematic cross-sectional view of the lines II-II′ shown in FIG. 4A.

FIG. 4A illustrates the first circuit area CA1 of the first sub-pixel SP1, and the pixel power line EVDD (or the second pixel power line EVDD2) partially overlapping the first circuit area CA1. FIG. 4B is a schematic cross-sectional view of lines II-II′ shown in FIG. 4A, schematically illustrating only the first substrate 110, and the pixel power lines EVDDs, the first light blocking layer LS1, the active layer 112a (or the first layer L1), and the gate electrode 112b (or the second layer L2), which are sequentially disposed on the first substrate 110.

Referring to FIG. 4A, in the display apparatus 100 according to one embodiment of the present disclosure, the pixel power line EVDD includes the first pixel power line EVDD1 disposed in the second direction (Y-axis direction) along one edge of the first sub-pixel SP1, and the second pixel power line EVDD2 partially overlapping the circuit area CA and disposed extending in the first direction (X-axis direction) from the first pixel power line EVDD1 (or in a direction to the right of the first direction (X-axis direction)).

As shown in FIG. 4A, the second pixel power line EVDD2 extends in the first direction (X-axis direction) from the first pixel power line EVDD1, so that it may partially overlap with the first circuit area CA1 of the first sub-pixel SP1. For example, the second pixel power line EVDD2 may partially overlap the first thin film transistor TR1 (shown in FIG. 4B) for driving the light emitting element layer of the first sub-pixel SP1.

As described above, by providing the second pixel power line EVDD2 and the first pixel power line EVDD1 as an integrated extension without being spaced apart, the area of the circuit area CA may be reduced by the omitted (or eliminated) horizontal width W1 (or horizontal length W1), so that the area of the light emission area EA may be relatively increased, thereby improving the light efficiency.

Meanwhile, in the display apparatus 100 according to one embodiment of the present disclosure, the first circuit area CA1 may further include the first light blocking layer LS1.

The first light blocking layer LS1 may be disposed between the first thin film transistor TR1 and the second pixel power line EVDD2. The first light blocking layer LS1 may block light incident through the first substrate 110 toward the active layer 112a, thereby minimizing threshold voltage changes of the transistor caused by external light.

Furthermore, in the display apparatus 100 according to one embodiment of the present disclosure, the first light blocking layer LS1 and the pixel power line EVDD may be designed by dividing roles. For example, the first light blocking layer LS1 may be designed to contribute to the role of stable driving of the thin film transistor 112, and the pixel power line EVDD may be designed to play the role of light blocking and power consumption improvement. Thus, in the display apparatus 100 according to one embodiment of the present disclosure, the first light blocking layer LS1 is not limited in the type and thickness of the metal (or conducting semiconductor or transparent electrode), and the pixel power line EVDD may be used as an opaque and low-resistance metal as it is used for light blocking and power consumption improvement.

In general, the main functions of the light blocking layer are light blocking and current saturation, and in the case of a conventional display apparatus, a stable voltage Vth is applied only when the source (or source electrode) of the thin film transistor and the light blocking layer are connected. In this case, on/off voltage is applied to the channel of the thin film transistor happens at the same time. However, if a pixel power line is disposed directly below the thin film transistor without the light blocking layer, the constant voltage of the pixel power line affects the channel of the thin film transistor, causing the voltage (Vth) to shift more when the gate voltage is applied (parasitic capacitance effect). This is because the constant voltage of the pixel power line is continuously applied to the lower part of the channel of the thin film transistor even when the gate voltage is not applied. Therefore, the source (or source electrode) of the thin film transistor and the light blocking layer should be designed in the same node.

The display apparatus 100 according to one embodiment of the present disclosure may have a stable voltage (Vth) characteristic by having the thin film transistor (or the first thin film transistor TR1) and the light blocking layer (or the first light blocking layer LS1) designed in the same node, as shown in FIG. 3, and by shielding the constant voltage parasitic capacitance of the pixel power line EVDD (or the first pixel power line EVDD1) with the light blocking layer (or the first light blocking layer LS1).

As a result, the display apparatus 100 according to one embodiment of the present disclosure is provided with the second pixel power line EVDD2 and the first pixel power line EVDD1 extended integrally without being spaced apart, so that the area of the light emission area EA may be increased by the reduced area of the circuit area CA, thereby improving the light efficiency. Also, by the first light blocking layer LS1 being disposed between the first thin film transistor TR1 and the second pixel power line EVDD2, a voltage may be stably applied to the source electrode 112c of the first thin film transistor TR1 without being affected by the constant voltage of the second pixel power line EVDD2.

Since the first light blocking layer LS1 is required to shield the constant voltage of the second pixel power line EVDD2, it may be arranged to overlap with the first thin film transistor TR1 and the second pixel power line EVDD2, as shown in FIG. 3 (or FIG. 4b).

Although not shown, in the display apparatus 100 according to one embodiment of the present disclosure, the first light blocking layer LS1 and the pixel power line EVDD may be formed through a halftone process utilizing one mask. Therefore, the display apparatus 100 according to one embodiment of the present disclosure may be easily manufactured because it is not necessary to separately align the formation positions of the light blocking layer and the pixel power line, compared to a conventional display apparatus in which the light blocking layer and the pixel power line are each formed using two masks. Furthermore, in a general display apparatus, when the alignment of the light blocking layer and the pixel power line is incorrect, the thickness of the interlayer insulating layer on the slope of the pixel power line EVDD is reduced, which may cause a shorting of the pixel power line and the reflective electrode, whereas in the display apparatus 100 according to one embodiment of the present disclosure, a separate alignment process for the first layer of light blocking layer LS1 and the pixel power line EVDD is not performed, so that a shorting of the pixel power line EVDD and the reflective electrode 117 may be prevented.

On the other hand, as shown in FIG. 4A, the area of the first light blocking layer LS1 may be smaller than the area of the second pixel power line EVDD2. This is because, when the area of the first light blocking layer LS1 is larger than the area of the second pixel power line EVDD2, the area of the light emission area EA may be reduced due to the area of the first light blocking layer LS1, and thus, the light efficiency may be reduced. Furthermore, when the area of the first light blocking layer LS1 is equal to the area of the second pixel power line EVDD2, it is difficult to form a contact structure of the second pixel power line EVDD2 and the drain electrode 112d of the first thin film transistor TR1. Therefore, the display apparatus 100 according to one embodiment of the present disclosure is provided with an area of the first light blocking layer LS1 that is smaller than the area of the second pixel power line EVDD2, so that the contact of the second pixel power line EVDD2 and the drain electrode 112d of the first thin film transistor TR1 may be easily implemented without reducing the light efficiency.

Referring to FIG. 3, the first thin film transistor TR1 may include the active layer 112a disposed on the first light blocking layer LS1, the gate electrode 112b disposed on the active layer 112a, and the source electrode 112c and the drain electrode 112d connected to a source area and a drain area, respectively, of the active layer 112a. The first circuit area CA1 comprising the first thin film transistor TR1 may further include the first storage capacitor Cst1 disposed adjacent to the first thin film transistor TR1.

As shown in FIGS. 3 and 4B, the first storage capacitor Cst1 may include the second pixel power line EVDD2, the first light blocking layer LS1 on the second pixel power line EVDD2, the first layer L1 on the first light blocking layer LS1 and disposed on the same layer as the active layer 112a, and the second layer L2 on the first layer L1 and disposed on the same layer as the gate electrode 112b. Here, the second pixel power line EVDD2 of the first storage capacitor Cst1 may be a part of the second pixel power line EVDD2. Also, the first light blocking layer LS1 of the first storage capacitor Cst1 may be a part of the first light blocking layer LS1.

Meanwhile, as shown in FIG. 4B, the second layer L2 of the first storage capacitor Cst1 may be electrically connected to the first light blocking layer LS1. Further, the first layer L1 of the first storage capacitor Cst1 may be applied with a voltage different from the second layer L2. For example, the first layer L1 and the second layer L2 may be applied with different voltages each other from the pad portion PA. Thus, an electric field may be formed between the first layer L1 and the second layer L2, and between the first layer L1 and the first light blocking layer LS1, so that the first layer L1, the second layer L2, and the first light blocking layer LS1 may be provided with the first storage capacitor Cst1. Since the second pixel power line EVDD2 disposed below the first light blocking layer LS1 is utilized as a power line, it may not be included in the first storage capacitor Cst1.

Thus, in the display apparatus 100 according to one embodiment of the present disclosure, the first storage capacitor Cst1 of the first sub-pixel SP1 may be implemented to have a double capacitance with the first layer L1, the second layer L2, and the first light blocking layer LS1.

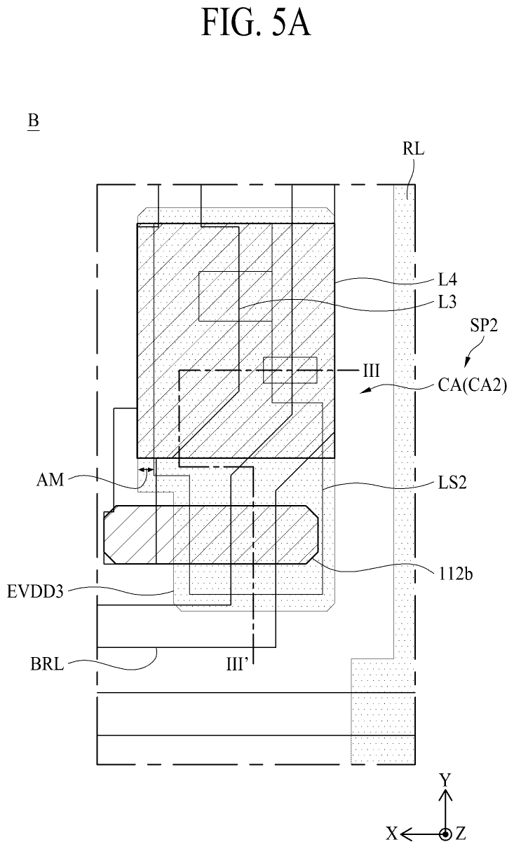

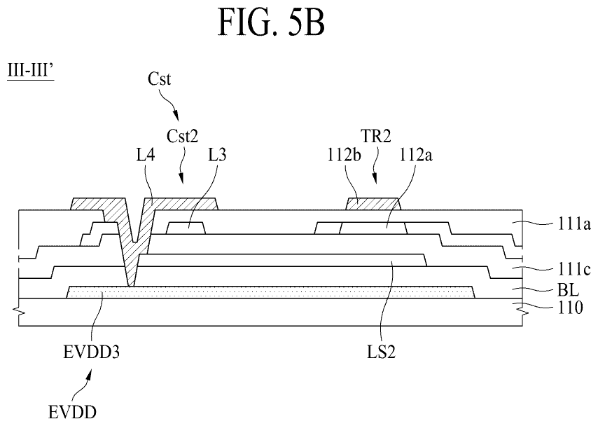

Hereinafter, with reference to FIGS. 5A and 5B, the circuit area CA (or the non-light emission area NEA) of the display apparatus 100 according to one embodiment of the present disclosure will be described in more detail. FIG. 5A is a schematic enlarged view of the portion B shown in FIG. 2, and FIG. 5B is a schematic cross-sectional view of the lines III-III′ shown in FIG. 5A.

FIG. 5A illustrates a second circuit area CA2 of the second sub-pixel SP2, and the pixel power line EVDD (or a third pixel power line EVDD3) partially overlapping the second circuit area CA2. FIG. 5B is a schematic cross-sectional view of the lines III-III′ shown in FIG. 5A, illustrating only the first substrate 110, and the pixel power lines EVDDs (or the third pixel power lines EVDD3), a second light blocking layer LS2, the active layer 112a (or the third layer L3), and the gate electrode 112b (or the fourth layer L4), which are sequentially disposed on the first substrate 110.

Referring to FIG. 5A, in the display apparatus 100 according to one embodiment of the present disclosure, the pixel power line EVDD may further include the third pixel power line EVDD3 that partially overlaps the second circuit area CA2 of the second sub-pixel SP2. The third pixel power line EVDD3 may be connected to the first pixel power line EVDD1 through branch wiring BRL.

Since the third pixel power line EVDD3 receives pixel power through the branch wiring BRL, it may be spaced apart from each of the second data line DL2 and the reference line RL, as shown in FIG. 2. In other words, the third pixel power line EVDD3 may be provided as a floating structure in the second circuit area CA2, and may be connected to the first pixel power line EVDD1 through the branch wiring BRL.

On the other hand, in the display apparatus 100 according to one embodiment of the present disclosure, the second circuit area CA2 may include the second thin film transistor TR2 and a second storage capacitor Cst2 disposed adjacent to the second thin film transistor TR2. Since the second thin film transistor TR2 has a similar structure to the first thin film transistor TR1, only differences from the first thin film transistor TR1 will be described below.

The second circuit area CA2 may further include the second light blocking layer LS2. The second light blocking layer LS2 may be disposed between the second thin film transistor TR2 and the third pixel power line EVDD3. The second light blocking layer LS2 may block light incident through the first substrate 110 toward the active layer 112a, thereby minimizing a threshold voltage change of the transistor caused by external light. As described above, the display apparatus 100 according to one embodiment of the present disclosure is provided with the pixel power line EVDD being at a lower part of the second light blocking layer LS2, so that the pixel power line EVDD and the second light blocking layer LS2 may function as light blocking, thereby having a double light blocking effect. Furthermore, by shielding the constant voltage of the third pixel power line EVDD3, the second light blocking layer LS2 may enable a voltage to be stably applied to the source electrode 112c of the second thin film transistor TR2.

Since the second light blocking layer LS2 is required to shield the constant voltage of the third pixel power line EVDD3, the second light blocking layer LS2 may be provided to overlap the second thin film transistor TR2 and the third pixel power line EVDD3, as shown in FIG. 5B.

On the other hand, as shown in FIG. 5a, the area of the second light blocking layer LS2 may be smaller than the area of the third pixel power line EVDD3. Thus, the display apparatus 100 according to one embodiment of the present disclosure may be provided with an area of the second light blocking layer LS2 smaller than the area of the third pixel power line EVDD3, so that the third pixel power line EVDD3 and the drain electrode of the second thin film transistor TR2 may contact easily without reducing the light efficiency.

Referring to FIG. 5B, the second thin film transistor TR2 may include an active layer 112a disposed on the second light blocking layer LS2, a gate electrode 112b disposed on the active layer 112a, and a source electrode and a drain electrode connected to a source area and a drain area, respectively, of the active layer 112a. The second circuit area CA2 including the second thin film transistor TR2 may further include a second storage capacitor Cst2 disposed adjacent to the second thin film transistor TR2.

As shown in FIG. 5B, the second storage capacitor Cst2 may include the third pixel power line EVDD3, a second light blocking layer LS2 on the third pixel power line EVDD3, a third layer L3 on the second light blocking layer LS2, and a fourth layer L4 disposed on the third layer L3. Here, the third pixel power line EVDD3 of the second storage capacitor Cst2 may be a part of the third pixel power line EVDD3. Also, the second light blocking layer LS2 of the second storage capacitor Cst2 may be a part of the second light blocking layer LS2. The third layer L3 may be disposed in the same layer as the active layer 112a. The fourth layer L4 may be disposed in the same layer as the gate electrode 112b.

Meanwhile, as shown in FIG. 5B, the fourth layer L4 of the second storage capacitor Cst2 may be electrically connected to the second light blocking layer LS2 and the third pixel power line EVDD3. Also, the third layer L3 of the second storage capacitor Cst2 may be supplied to a voltage different from the fourth layer L4 and/or the second light blocking layer LS2. Thus, an electric field may be formed between the third layer L3 and the fourth layer L4, and between the third layer L3 and the second light blocking layer LS2, so that the third layer L3, the fourth layer L4, and the second light blocking layer LS2 may be provided as the second storage capacitor Cst2.

Thus, in the display apparatus 100 according to one embodiment of the present disclosure, the second storage capacitor Cst2 of the second sub-pixel SP2 may be implemented as a double capacitance using the third layer L3, the fourth layer L4, and the second light blocking layer LS2.

On the other hand, in the display apparatus 100 according to one embodiment of the present disclosure, the third sub-pixel SP3 may be provided with a structure similar to the second sub-pixel SP2, and the fourth sub-pixel SP4 may be provided with a structure similar to the first sub-pixel SP1.

For example, referring to FIG. 2, the pixel power line EVDD may include a fourth pixel power line EVDD4 partially overlapping the third circuit area CA3 of the third sub-pixel SP3, and the fourth pixel power line EVDD4 may be spaced apart from the reference line RL and the third data line DL3. Also, the pixel power line EVDD may include a fifth pixel power line EVDD5 partially overlapping the fourth circuit area CA4 of the fourth sub-pixel SP4, the fifth pixel power line EVDD5 may extend in the first direction (X-axis direction) (or a left direction of the first direction (X-axis direction)) from the first pixel power line EVDD1 disposed along one edge (or a right edge) of the fourth sub-pixel SP4. The fifth pixel power line EVDD5 is an area extending from the first pixel power line EVDD1, and thus may be expressed in terms of a second pixel line extension area or a second pixel line extension portion.

Accordingly, in the display apparatus 100 according to one embodiment of the present disclosure, the circuit areas CA1, CA4 of each of the first sub-pixel SP1 and the fourth sub-pixel SP4 may have a reduced or minimized area, so that the area of the light emission area EA of each of the first sub-pixel SP1 and the fourth sub-pixel SP4 may be relatively increased, thereby maximizing the improvement in light efficiency.

Furthermore, the display apparatus 100 according to one embodiment of the present disclosure is configured such that the pixel power lines EVDDs in each of the first sub-pixel SP1 and the fourth sub-pixel SP4 have an expanded structure, so that the overall area of the pixel power lines may be increased and the current density may be reduced, thereby enabling the display area DA to be driven with low power, therefore the overall power consumption may be reduced.

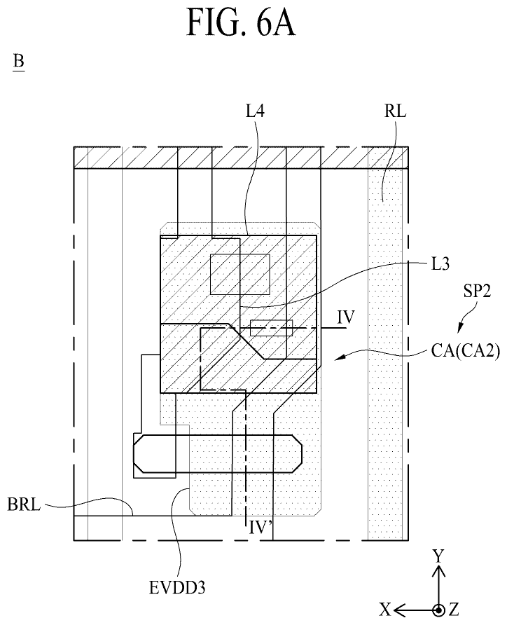

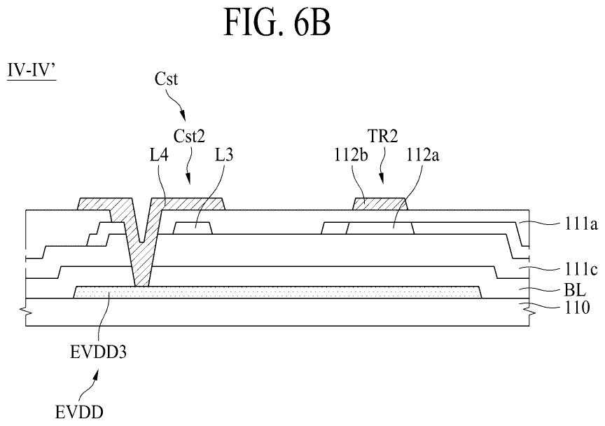

Hereinafter, with reference to FIGS. 6A and 6B, another example of the second circuit area CA2 of the display apparatus 100 according to one embodiment of the present disclosure will be described. FIG. 6A is a schematic enlarged view illustrating another example of FIG. 5A, and FIG. 6B is a schematic cross-sectional view of lines IV-IV′ shown in FIG. 6A.

FIG. 6A illustrates the second circuit area CA2 of a second sub-pixel SP2, and the pixel power line EVDD (or the third pixel power line EVDD3) partially overlapping the second circuit area CA2. FIG. 6B is a schematic cross-sectional view of lines IV-IV′ shown in FIG. 6A, illustrating only the first substrate 110, and the pixel power lines EVDD (or the third pixel power lines EVDD3), the active layer 112a (or the third layer L3), and the gate electrode 112b (or the fourth layer L4), which are sequentially disposed on the first substrate 110.

As shown in FIGS. 6A and 6B, in the display apparatus 100 according to one embodiment of the present disclosure, another example of the second circuit area CA2 is the same as the second circuit area CA2 of FIG. 5A described above, except that the second light blocking layer LS2 is omitted (or removed). Accordingly, the same drawing symbols have been assigned to the same configuration, and only the different configurations will be described hereinafter.

In the second circuit area CA2 of FIG. 5A, the second light blocking layer LS2 is disposed on the third pixel power line EVDD3, so that the second light blocking layer LS2 shields the second thin film transistor TR2 from being affected by the constant voltage of the third pixel power line EVDD3.

In contrast, in another example of the second circuit area CA2 of FIG. 6A, the third pixel power line EVDD3 may not only be capable of applying a pixel voltage to the second thin film transistor TR2, but may also be disposed below the second thin film transistor TR2 to block light incident through the first substrate 110 toward the active layer 112a of the second thin film transistor TR2. In other words, in another example of the second circuit area CA2 of FIG. 6A, the third pixel power line EVDD3 may be configured to have both a function of applying a pixel voltage and a function of blocking external light. For example, the third pixel power line EVDD3 may be configured with an opaque metal material so that it has both a function of applying pixel voltage and a function of blocking external light. Accordingly, another example of the second circuit area CA2 of FIG. 6A may not be provided with the second light blocking layer LS2.

On the other hand, in the other example of the second circuit area CA2 of FIG. 6A, since the second light blocking layer LS2 is not disposed, the ashing margin AM (or halftone process margin) provided between the third pixel power line EVDD3 and the second light blocking layer LS2 of FIG. 5A may be omitted (or removed). Thus, in another example of the second circuit area CA2 of FIG. 6A, the area of the second circuit area CA2 may be reduced as much as the ashing margin AM (or halftone process margin) of FIG. 5a is omitted, and the area of the light emission area EA of the second sub-pixel SP2 may be relatively increased accordingly. Therefore, the other example of the second circuit area CA2 of FIG. 6A may have a further decrease in area compared to the second circuit area CA2 of FIG. 5A, so that the area of the light emission area EA may be further increased relatively, thereby further improving the light efficiency of the second sub-pixel SP2.

Referring again to FIGS. 6A and 6B, the third pixel power line EVDD3 may partially overlap the second circuit area CA2 of the second sub-pixel SP2 and be spaced apart from the reference line RL as the pixel voltage is applied. More specifically, the third pixel power line EVDD3 partially overlaps the second thin film transistor TR2 below the second thin film transistor TR2 of the second sub-pixel SP2, and may be electrically connected to the first pixel power line EVDD1 through the branch wiring BRL. Accordingly, in another example of the second circuit area CA2, the third pixel power line EVDD3 may apply a pixel voltage supplied from the first pixel power line EVDD1 to the second thin film transistor TR2.

Other examples of the second circuit area CA2 of FIG. 6A may include a second storage capacitor Cst2 disposed adjacent to the second thin film transistor TR2. As described above, the other example of the second circuit area CA2 of FIG. 6A does not include the second light blocking layer LS2, so that the structure of the second storage capacitor Cst2 of FIG. 6A may be different from the structure of the second storage capacitor Cst2 of FIG. 5A.

As shown in FIG. 6B, the second storage capacitor Cst2 may include the third pixel power line EVDD3, the third layer L3 disposed on the third pixel power line EVDD3, and the fourth layer L4 disposed on the third layer L3. Here, the third pixel power line EVDD3 of the second storage capacitor Cst2 may be a part of the third pixel power line EVDD3. Also, the third layer L3 may be disposed on the same layer as the active layer 112a. The fourth layer L4 may be disposed on the same layer as the gate electrode 112b.

Meanwhile, as shown in FIG. 6B, the fourth layer L4 of the second storage capacitor Cst2 may be electrically connected to the third pixel power line EVDD3. Also, the third layer L3 of the second storage capacitor Cst2 may be supplied to a voltage different from the fourth layer L4. Thus, an electric field may be formed between the third layer L3 and the fourth layer L4, and between the third layer L3 and the third pixel power line EVDD3, so that the third layer L3 and the fourth layer L4 and the third pixel power line EVDD3 may be provided as the second storage capacitor Cst2.

Thus, in another example of the second circuit area CA2 of FIG. 6B, the second storage capacitor Cst2 may be implemented as a double capacitance with the third layer L3 and the fourth layer L4 and the third pixel power line EVDD3.

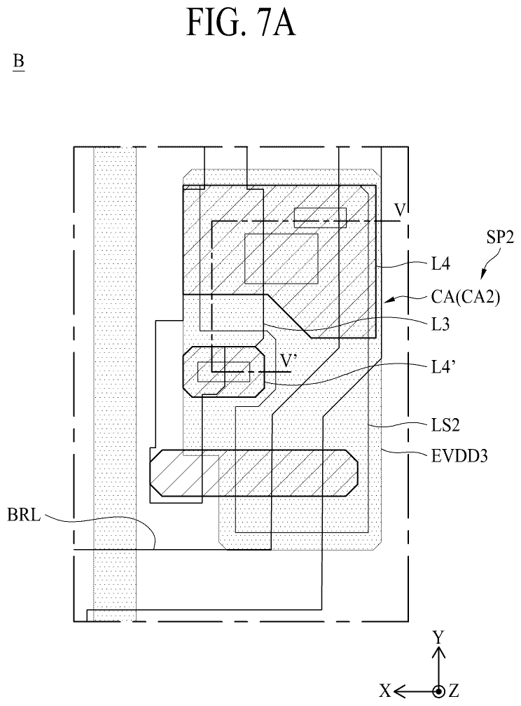

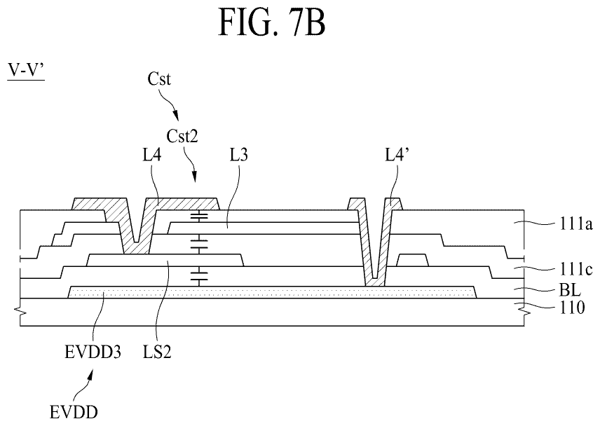

Hereinafter, with reference to FIGS. 7A and 7B, another example of the second circuit area CA2 of the display apparatus 100 according to one embodiment of the present disclosure will be described. FIG. 7A is a schematic enlarged view illustrating another example of FIG. 5A, and FIG. 7B is a schematic cross-sectional view of the lines V-V′ shown in FIG. 7A.

FIG. 7A illustrates the second circuit area CA2 of the second sub-pixel SP2, and the pixel power line EVDD (or the third pixel power line EVDD3) partially overlapping the second circuit area CA2. FIG. 7B is a schematic cross-sectional view of the lines V-V′ shown in FIG. 7A, illustrating only the first substrate 110, and the pixel power lines EVDD (or the third pixel power lines EVDD3), the second light blocking layer LS2, the third layer L3, and the fourth layer L4, which are sequentially disposed on the first substrate 110.

As shown in FIGS. 7A and 7B, in the display apparatus 100 according to one embodiment of the present disclosure, another example of the second circuit area CA2 is the same as the second circuit area CA2 of FIG. 5a described above, except that the structure of the second storage capacitor Cst2 has been changed. Therefore, the same drawing symbols have been assigned to the same configuration, and only the different configuration will be described hereinafter.

The second storage capacitor Cst2 of FIG. 5A mentioned above, has a stacked structure of the third pixel power line EVDD3, the second light blocking layer LS2, the third layer L3, and the fourth layer L4. In the stacked structure of the second storage capacitor Cst2, the fourth layer L4 is electrically connected to the second light blocking layer LS2 and the third pixel power line EVDD3, and the third layer L3 may be configured to be applied with a voltage different from the fourth layer L4 and/or the second light blocking layer LS2. Thus, the second storage capacitor Cst2 of FIG. 5A may be implemented to have a double capacitance with the third layer L3, the fourth layer L4, and the second light blocking layer LS2.

In contrast, the second storage capacitor Cst2 of FIG. 7A has a stacked structure of the third pixel power line EVDD3, the second light blocking layer LS2, the third layer L3, and the fourth layer L4. In the stacked structure of the second storage capacitor Cst2, the fourth layer L4 may be electrically connected to the second light blocking layer LS2, and the third layer L3 may be electrically connected to the third pixel power line EVDD3 through contact wiring L4′ formed on the same layer as the fourth layer L4. For example, the contact wiring L4′ may be electrically connected to the third layer L3 and the third pixel power line EVDD3 through contact holes penetrating the buffer layer BL and the passivation layer 111c and the gate insulating layer 111a.

In the second storage capacitor Cst2 of FIG. 7A, the third layer L3 may be configured to be applied with a voltage different from the fourth layer L4. Accordingly, since an electric field may be formed between the third layer L3 and the fourth layer L4, between the third layer L3 and the second light blocking layer LS2, and between the second light blocking layer LS2 and the third pixel power line EVDD3, the third layer L3, the fourth layer LA, the second light blocking layer LS2, and the third pixel power line EVDD3 may be provided with the second storage capacitor Cst2 including a triple capacitance.

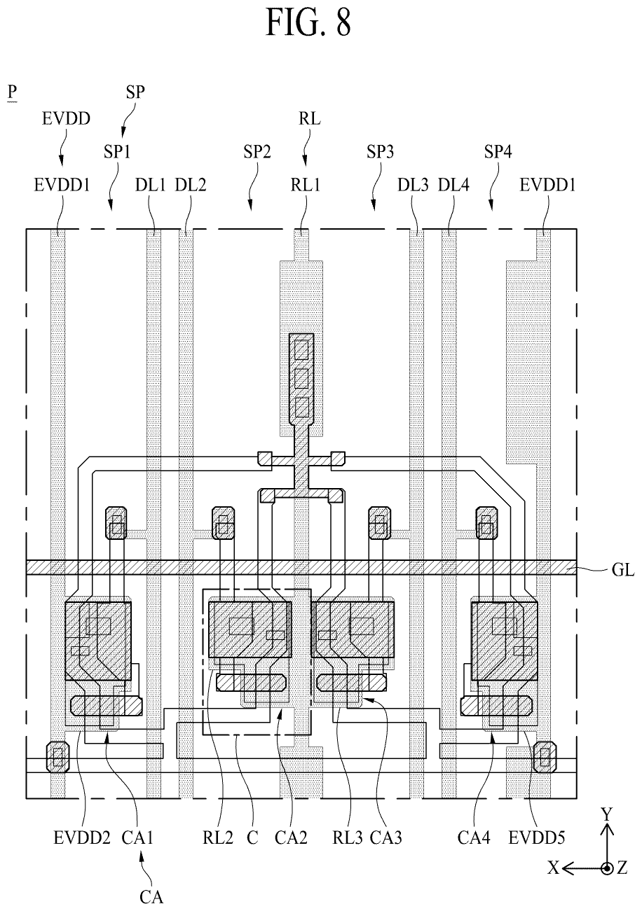

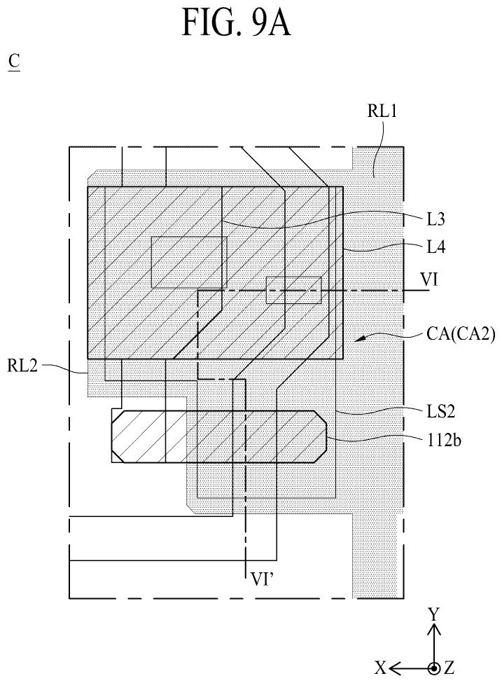

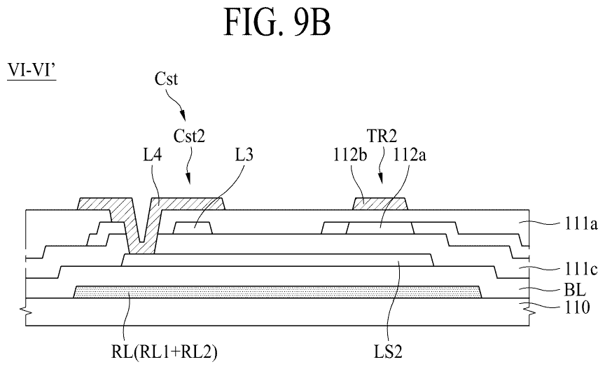

FIG. 8 is a schematic plan view of a display apparatus according to a second embodiment of the present disclosure, FIG. 9A is a schematic enlarged view of the portion C shown in FIG. 8, and FIG. 9B is a schematic cross-sectional view of the lines VI-VI′ shown in FIG. 9A.

Referring now to FIGS. 8 to 9B, the display apparatus 100 according to a second embodiment of the present disclosure is the same as the display apparatus according to FIG. 1 above, except that the structure of the second circuit area CA2 of the second sub-pixel SP2 and the third circuit area CA3 of the third sub-pixel SP3 has been changed. Therefore, the same drawing symbols have been assigned to the same configuration, and only the different configurations will be described hereinafter.

In the display apparatus according to FIG. 1, the third pixel power line EVDD3 is disposed in the second circuit area CA2, and the third pixel power line EVDD3 is connected to the first pixel power line EVDD1 through the branch wiring BRL. Accordingly, the display apparatus according to FIG. 1 may have a structural feature including the second storage capacitor Cst2 which has a stacked structure of the second light blocking layer LS2, the third layer L3 and the fourth layer L4 on the third pixel power line EVDD3.

In contrast, in the case of the display apparatus according to FIG. 8, the reference line RL disposed spaced apart from the pixel power line EVDD may be provided in a structure extending into the second circuit area CA2 of the second sub-pixel SP2. For example, the reference lines RL may include a first reference line RL1 disposed along one edge of the second sub-pixel SP2, and a second reference line RL2 partially overlapping the second circuit area CA2 of the second sub-pixel SP2. Here, one edge of the second sub-pixel SP2 may mean between the second sub-pixel SP2 and the third sub-pixel SP3.

As shown in FIG. 8, the first reference line RL1 may extend in the second direction (Y-axis direction) between the second sub-pixel SP2 and the third sub-pixel SP3. Also, the second reference line RL2 may be disposed extending in the first direction (X-axis direction) (or a left direction of the first direction (X-axis direction)) from the first reference line RL1. Thus, the second reference line RL2 may partially overlap the second circuit area CA2, and may be an area extending from the first reference line RL1. Since the second reference line RL2 is an area extending in a leftward direction from the first reference line RL1, it may be expressed in terms of a first reference line extension area or a first reference line extension portion.

As shown in FIG. 9A, the display apparatus 100 according to the second embodiment of the present disclosure has a structure in which the second reference line RL2 extends to partially overlap the second circuit area CA2, so that, unlike the display apparatus 100 of FIG. 2, the first reference line RL1 and the second reference line RL2 may not be spaced apart. Accordingly, the display apparatus 100 according to the second embodiment of the present disclosure may be provided with the second reference line RL2 and the first reference line RL1 extending integrally without being spaced apart, so that the horizontal width (or horizontal length) of the area of the second circuit area CA2 may be reduced, and thus, the area of the light emission area EA of the second sub-pixel SP2 may be relatively increased, thereby improving the light efficiency. The logic is the same as that in the display apparatus 100 of FIG. 2, the second pixel power line EVDD2 and the first pixel power line EVDD1 are not spaced apart and are provided in an integrated manner, so that the area of the circuit area CA may be reduced by the omitted (or removed) horizontal width W1 (or horizontal length W1), thus the area of the light emission area EA may be increased relatively, therefore the light efficiency may be improved.

Referring to FIG. 9B, the second circuit area CA2 of the second sub-pixel SP2 may include the second thin film transistor TR2 for driving the light emitting element layer of the second sub-pixel SP2. Here, the second reference line RL2 may be disposed below the second thin film transistor TR2 and may be disposed to overlap the second thin film transistor TR2.

Meanwhile, the second circuit area CA2 of the second sub-pixel SP2 may further include the second light blocking layer LS2 disposed between the second thin film transistor TR2 and the second reference line RL2. The second light blocking layer LS2 may block light incident through the first substrate 110 toward the active layer 112a, thereby minimizing a threshold voltage change of the transistor caused by external light. Further, the second light blocking layer LS2 may shield the voltage of the second reference line RL2, thereby enabling a stable voltage to be applied to the second thin film transistor TR2

As a result, the display apparatus 100 according to the second embodiment of the present specification may be provided with a structure in which the second pixel power line EVDD2 extends from the first pixel power line EVDD1 into the first circuit area CA1 of the first sub-pixel SP1, and the second reference line RL2 extends from the first reference line RL1 into the second circuit area CA2 of the second sub-pixel SP2. Accordingly, the display apparatus 100 according to the second embodiment of the present disclosure may reduce an area of the first circuit area CA1 of the first sub-pixel SP1 and an area of the second circuit area CA2 of the second sub-pixel SP2, so that, relatively, an area of the light emission area EA of the first sub-pixel SP1 and an area of the light emission area EA of the second sub-pixel SP2 may be increased, thus an improvement in light efficiency may be maximized.

On the other hand, in the display apparatus 100 according to the second embodiment of the present disclosure, the third sub-pixel SP3 may be provided with a structure similar to the second sub-pixel SP2, and the fourth sub-pixel SP4 may be provided with a structure similar to the first sub-pixel SP1.

For example, referring to FIG. 8, the reference line RL may include the third reference line RL3 that partially overlaps the third circuit area CA3 of the third sub-pixel SP3, and the third reference line RL3 may extend in the first direction (X-axis direction) (or a rightward direction of the first direction (X-axis direction)) from the first reference line RL1. Since the third reference line RL3 is an area extending in a rightward direction from the first reference line RL1, it may be expressed in terms of a second reference line extension area or a second reference line extension portion.

The pixel power line EVDD may include the fifth pixel power line EVDD5 that partially overlaps the fourth circuit area CA4 of the fourth sub-pixel SP4, the fifth pixel power line EVDD5 may extend in the first direction (X-axis direction) (or a left direction of the first direction (X-axis direction)) from the first pixel power line EVDD1 disposed along one edge (or a right edge) of the fourth sub-pixel SP4.

Accordingly, the display apparatus 100 according to the second embodiment of the present disclosure may have a reduced or minimized area of the circuit areas CA1, CA2, CA3, CA4 of each of the first to fourth sub-pixels SP1, SP2, SP3, and SP4, so that the area of the light emission areas of each of the first to fourth sub-pixels SP1, SP2, SP3, and SP4 may be relatively increased, thereby maximizing the improvement in light efficiency.

Furthermore, the display apparatus 100 according to the second embodiment of the present disclosure is configured to have an extended structure of the pixel power lines EVDDs in each of the first sub-pixel SP1 and the fourth sub-pixel SP4, such that the overall area of the pixel power lines may be increased and the current density may be reduced, thereby enabling it to be operated with low power, therefore the overall power consumption may be reduced.

While embodiments of the present disclosure are described in more detail with reference to the accompanying drawings, the present disclosure is not necessarily limited to these embodiments but may be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this specification should be construed to be included within the scope of the claims of this specification.

The display apparatus according to the present disclosure is configured such that the pixel power line partially overlaps the circuit area, thus the area of the light emission area may be increased in response to a decrease in the area of the circuit area, and therefore the light efficiency may be improved.

The display apparatus according to the present disclosure may be configured to have an extended pixel power line, thereby reducing power consumption.

In the display apparatus according to the present disclosure, the light blocking layer is disposed between the thin film transistor and the pixel power line, thus the thin film transistor (or light emitting element layer) may be driven stably.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate having a display area in which a plurality of sub-pixels are disposed and a non-display area surrounding the display area; and
a pixel power line extending from the non-display area to the display area,
wherein each of the plurality of sub-pixels comprises a light emission area and a circuit area adjacent to the light emission area, and
wherein the pixel power line comprises:
a first pixel power line disposed along one edge of one of the plurality of sub-pixels; and
a second pixel power line partially overlapping the circuit area and extending from the first pixel power line.

2. The display apparatus of claim 1,
wherein the plurality of sub-pixels comprise a first sub-pixel, a second sub-pixel, a third sub-pixel, and a fourth sub-pixel disposed sequentially in one direction,
wherein the first pixel power line is disposed along one edge of the first sub-pixel, and
wherein the second pixel power line partially overlaps a first circuit area of the first sub-pixel.

3. The display apparatus of claim 2,
wherein the light emission area of the first sub-pixel comprises a light emitting element layer,
wherein the first circuit area comprises a first thin film transistor for driving the light emitting element layer of the first sub-pixel, and
wherein the second pixel power line partially overlaps the first thin film transistor below the first thin film transistor.

4. The display apparatus of claim 3, wherein the first circuit area further comprises a first light blocking layer disposed between the first thin film transistor and the second pixel power line.

5. The display apparatus of claim 4, wherein the first light blocking layer overlaps the first thin film transistor and the second pixel power line.

6. The display apparatus of claim 4, wherein an area of the first light blocking layer is smaller than an area of the second pixel power line.

7. The display apparatus of claim 3, wherein the first thin film transistor comprises:
an active layer disposed on the first light blocking layer;
a gate electrode disposed on the active layer; and
a source electrode and a drain electrode connected to each of a source area and a drain area of the active layer.

8. The display apparatus of claim 7,
wherein the first circuit area further comprises a first storage capacitor disposed adjacent to the first thin film transistor, and
wherein the first storage capacitor comprises:
the second pixel power line;
the first light blocking layer on the second pixel power line;
a first layer on the first light blocking layer and disposed on the same layer as the active layer; and
a second layer disposed on the first layer and disposed on the same layer as the gate electrode.

9. The display apparatus of claim 8,
wherein the second layer of the first storage capacitor is electrically connected to the first light blocking layer, and
wherein the first layer is applied with a voltage different from the second layer.

10. The display apparatus of claim 2,
wherein the pixel power line comprises a third pixel power line partially overlapping a second circuit area of the second sub-pixel,
wherein the second circuit area comprises a second storage capacitor disposed adjacent to the second thin film transistor, and
wherein the second storage capacitor comprises:
the third pixel power line;
a second light blocking layer on the third pixel power line;
a third layer on the second light blocking layer;
a fourth layer disposed on the third layer.

11. The display apparatus of claim 10,
wherein the fourth layer of the second storage capacitor is electrically connected to the second light blocking layer and the third pixel power line, and
wherein the third layer of the second storage capacitor is applied with a voltage different from the fourth layer and/or the second light blocking layer.

12. The display apparatus of claim 2, further comprising:
a reference line spaced apart from the pixel power line,
wherein the pixel power line comprises a third pixel power line partially overlapping a second circuit area of the second sub-pixel, and
wherein the third pixel power line is spaced apart from the reference line.

13. The display apparatus of claim 12, wherein the third pixel power line partially overlaps the second thin film transistor below the second thin film transistor of the second sub-pixel, and is electrically connected to the first pixel power line through branch wiring.

14. The display apparatus of claim 12,
wherein the second circuit area comprises a second storage capacitor disposed adjacent to the second thin film transistor,
wherein the second storage capacitor comprises,
the third pixel power line;
a third layer on the third pixel power line; and
a fourth layer disposed on the third layer,
wherein the fourth layer electrically is connected to the third pixel power line, and
wherein the third layer is applied with a voltage different from the fourth layer.

15. The display apparatus of claim 10,
wherein the fourth layer of the second storage capacitor is electrically connected to the second light blocking layer,
wherein the third layer of the second storage capacitor is electrically connected to the third pixel power line, and
wherein the third layer is applied with a voltage different from the fourth layer.

16. The display apparatus of claim 2, further comprising:
a reference line spaced apart from the pixel power line,
wherein the reference line comprises:
a first reference line disposed along one edge of the second sub-pixel, and
a second reference line partially overlapping a second circuit area of the second sub-pixel.

17. The display apparatus of claim 16, wherein the second reference line is an area extending from the first reference line.

18. The display apparatus of claim 17, wherein the second circuit area of the second sub-pixel comprises a second thin film transistor for driving the light emitting element layer of the second sub-pixel,
wherein the second reference line is disposed below the second thin film transistor, and partially overlaps the second thin film transistor.

19. The display apparatus of one of claim 18, wherein the second circuit area of the second sub-pixel further comprises a second light blocking layer disposed between the second thin film transistor and the second reference line.

20. The display apparatus of one of claim 16,
wherein the reference line further comprises a third reference line partially overlapping a third circuit area of a third sub-pixel, and
wherein the third reference line extends from the first reference line.
